(19) United States
(12) Patent Application Publication
(10) Pub. No.: US 2013/0245973 A1
(43) Pub. Date: Sep. 19, 2013

(54) APPARATUS, COMPUTER PROGRAM, METHOD, AND SYSTEM FOR ACQUIRING AND ANALYZING BATTERY METRICS

(71) Applicant: SMARTMED USA INC., Kansas City, KS (US)

(72) Inventors: Charles Andrew Ross, JR., Kansas City, KS (US); Steve Phillips, Olathe, KS (US); James W. Farnham, IV, Olathe, KS (US)

(73) Assignee: SmartMed USA Inc., Kansas City, KS (US)

(21) Appl. No.: 13/832,307

(22) Filed: Mar. 15, 2013

Related U.S. Application Data
(60) Provisional application No. 61/611,660, filed on Mar. 16, 2012.

(51) Int. Cl. G01R 31/36

(52) U.S. Cl. CPC G01R 31/3627
USPC 702/63

(57) ABSTRACT

An apparatus, computer program, method, and system for acquiring and analyzing battery metrics. The apparatus, computer program, method, and system are directed to acquiring operating metrics for a battery, for wirelessly communicating the acquired metrics to a computing device executing the computer program, for determining pertinent operation information associated with battery life from the acquired metrics, and for presenting a user with the metrics, the status information, or the operating parameters of the battery.

### RELATED APPLICATION

This non-provisional patent application claims priority benefit, with regard to all common subject matter, of earlier filed U.S. Provisional Patent Application No. 61/611,660 filed Mar. 16, 2012, and entitled “COMPUTER PROGRAM, METHOD, AND SYSTEM FOR ACQUIRING BATTERY METRICS AND FOR CALCULATING A BATTERY LIFE.” The identified earlier-filed provisional patent application is hereby incorporated by reference in its entirety into the present non-provisional application.

### FIELD

Embodiments of the present invention are directed to an apparatus, a computer program, a method, and a system for acquiring and analyzing battery metrics. In particular, the apparatus, computer program, method, and system are directed to acquiring metrics from a battery, for wirelessly communicating the acquired metrics to a computing device executing the computer program, for determining status information and operating parameters for the battery based on the metrics and known battery specifications, and for presenting a user with the metrics, the status information, or the operating parameters of the battery.

### BACKGROUND

Many present-day devices are powered by batteries. In some circumstances, failure of the devices due to low-power or non-power may be detrimental to such devices or dangerous to users of the devices. For example, portable defibrillators used in medical procedures to deliver therapeutic doses of electrical energy to a patient's heart are commonly battery-powered. A fully-charged battery for a defibrillator is a necessity to insure accurate and precise use of the defibrillator. Medical service providers are required to expend extensive amounts of time measuring and testing the operating metrics of batteries used in defibrillators (or other battery-powered devices) to insure the defibrillators are operational and functionally ready. In particular, medical staff personnel are generally responsible for measuring and/or testing the status of batteries and for reporting and recording the results of such measurements and tests. The medical staff personnel are commonly required to execute these measurements and/or tests multiple times throughout a twenty-four hour period. In a modest sized medical service facility, which may house multiple defibrillators (or other battery-powered devices), such measurements and tests consume valuable staff hours and require the staff personnel to temporarily abandon their other responsibilities.

In addition to defibrillators, other battery-powered devices that experience low-battery power or complete battery failure can pose significant problems. Other examples may include battery-powered sump pumps, where a low-charged or non-charged battery for a sump pump may result in the sump pump being non-operational and a building's lower floors becoming flooded. Boats, motorcycles, fleet vehicles, exit lights, wheelchairs, back-up generators and security systems relying on battery power, at least in part, also require continual monitoring and testing of their associated batteries.

### SUMMARY

Embodiments of the present invention include a system and a method for acquiring metrics from a battery, with the system broadly including: a battery metrics acquisition system for acquiring metrics from a battery; and a non-transitory computer readable storage medium with a computer program stored thereon, such that the computer program instructs a processor to receive the metrics acquired by the battery metrics acquisition system; analyze the metrics to determine status information and operating parameters of the battery; provide to a user a set of computer-executable instructions that when executed by a user's electronic device, generate a user interface displayable on an electronic display coupled to the user's electronic device; and present to the user, via the user interface, one or more of the metrics, the status information, or the operating parameters of the battery.

Embodiments of the present invention include an additional method for acquiring metrics from a battery, with the steps of the method including: providing a battery metrics acquisition system for acquiring metrics from a battery; receiving the metrics acquired by the battery metrics acquisition system; analyzing the metrics to determine status information and operating parameters of the battery; presenting one or more of the metrics, the status information, or the operating parameters of the battery; receiving a threshold value associated with the battery; analyzing the metrics, the status information, or the operating parameters of the battery to determine if any of the metrics, the status information, or the operating parameters violate the threshold value; and upon a determination that any of the metrics, the status information, or the operating parameters violate the threshold value, sending an alert.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the present invention will be apparent from the following detailed description of the embodiments and the accompanying drawing figures.

### BRIEF DESCRIPTION OF THE DRAWING FIGURES

Embodiments of the present invention are described in detail below with reference to the attached drawing figures, wherein:

FIG. 1 is a perspective view of an illustrative battery metrics acquisition system according to embodiments of the present invention;

FIG. 2 is a schematic depiction of an interior of the battery metrics acquisition system shown in FIG. 1;

FIG. 3 is a wiring diagram of an electronics module included in the battery metrics acquisition system shown in FIG. 1;

FIG. 4 is a schematic depiction of a system for acquiring and analyzing battery metrics according to embodiments of the present invention;

FIG. 5 is a flow chart of a method for acquiring metrics from a battery according to embodiments of the present invention; and

FIG. 6 is a flow chart of an additional method for acquiring metrics from a battery according to embodiments of the present invention.

The drawing figures do not limit the present invention to the specific embodiments disclosed and described herein. The drawings are not necessarily to scale, emphasis instead being placed upon clearly illustrating the principles of the invention.

### DETAILED DESCRIPTION OF THE EMBODIMENTS

The following detailed description of the invention references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the present invention. The following detailed description is, therefore, not to be taken in a limiting sense. The scope of the present invention is defined only by the appended claims, along with the full scope of equivalents to which such claims are entitled.

In this description, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

Embodiments of the present invention include an apparatus, computer program, method, and system for acquiring and analyzing battery metrics. The computer program of embodiments of the present invention may include a primary computer program that is run on one or more external server devices and/or external computing devices and a secondary computer program that is run on a battery metrics acquisition system, each of which will be discussed in more detail below.

### BATTERY METRICS ACQUISITION SYSTEM

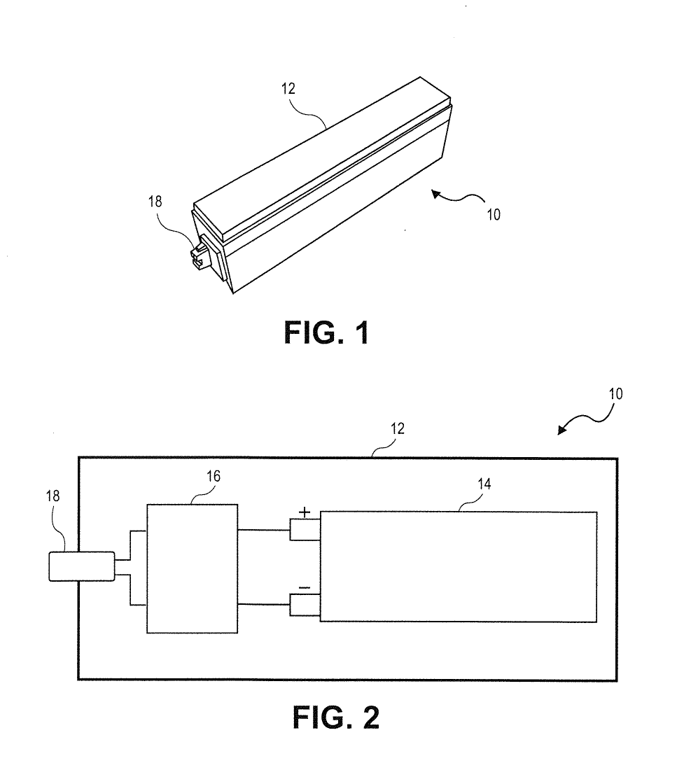

A battery metrics acquisition system 10 of embodiments of the present invention, as illustrated in FIGS. 1-2, is directed to a system for acquiring metrics associated with a battery and broadly comprises a housing 12; one or more batteries 14 positioned within the housing, the metrics of which are to be acquired; one or more electronics modules 16 positioned within the housing, which may include one or more sensors, amplifiers, converters, a data bus, processing elements, memory elements, and a communications interface; and a power connection interface 18 for providing an electrical connection between the battery and a device to be powered. It should also be understood that certain components (i.e., the battery 14, the electronics module 16, and the power connection interface 18) may be electrically connected via electric cables, wires, or the like. Embodiments of the present invention permit users to acquire metrics from batteries and to perform analyses on such metrics. Embodiments of the present invention further provide for the sensed metrics to be communicated, via the communications interface, to an external computing device that is accessible by users, so as to perform additional analyses and to conduct status checks and tests on the batteries. Thus, embodiments of the present invention include a battery metrics acquisition system for acquiring battery metrics and transmitting the metrics to users, such that the user can analyze the metrics and perform status checks on the battery. The battery metrics acquisition system 10 may be used by medical service providers, facility maintenance staff, fleet vehicle owners, ambulance services, airline services, or any by any other entity that requires consistent monitoring and testing of batteries for electronic devices.

The housing 12 of the battery metrics acquisition system 10 may preferably be sized to accommodate the remaining components of the system. For instance, embodiments of the present invention contemplate that the one or more batteries 14 and the electronics modules 16, as are described in more detail below, may be located within the housing. As can be appreciated, a size of the housing 12 may vary depending on sizes of the components of the battery metrics acquisition system 10. For instance, a housing used in a battery metrics acquisition system that acquires metrics for smaller batteries may have a smaller size, while a housing used in a battery metrics acquisition system for acquiring metrics for larger or multiple batteries may have a larger size. For example, a battery metrics acquisition system used to acquire metrics for a NEDA 1604 9V battery may have a housing that is substantially smaller than a battery metrics acquisition system used to acquire metrics on a 12V SLI vehicle battery. In additional embodiments, the housing 12 may not accommodate the battery 14. Such embodiments may be employed, for instance, when the one or more batteries of the battery metrics acquisition system 10 are large in size, thus making it difficult or cumbersome to form a housing capable of enclosing the entire battery. In such embodiments, the housing 12 may only be required to enclose the electronics module 16 and thus may be formed with a smaller size. The housing 12 may be formed of ABS or other material suitable for rugged operation, such that one or more batteries 14 and the electronics module 16 can withstand exposure to ambient elements, including moisture, temperatures, pressures, impacts, or the like. In certain embodiments, an exterior of the housing 12 may include rubber impact pads to further protect the battery metrics acquisition system from high-level impacts.

In certain embodiments, the exterior of the housing 12 may include one or more user interface controls, such as dials, buttons, knobs, or the like, which may be used to control the function of the battery metrics acquisition system 10. The housing may also include an electronic display (not shown) that provides users with information related to the functionality of the battery metrics acquisition system 10. In certain embodiments the electronic display may include a liquid crystal display, cathode ray tube, light emitting diode, plasma display, or the like, which is capable of displaying graphics, text, images, videos, or the like to the users.

The one or more batteries 14 may include any type of device that is capable of converting stored chemical energy into electrical energy. For instance, the batteries 14 may include any original equipment manufacturer (OEM)-type batteries, including lithium-ion, alkaline, zinc-carbon, lead-acid, nickel-cadmium, nickel metal-hydride, or the like. The batteries 14 may include batteries of various sizes and shapes, and may also be used to provide electrical energy to a wide range of devices, appliances, applications, and the like.

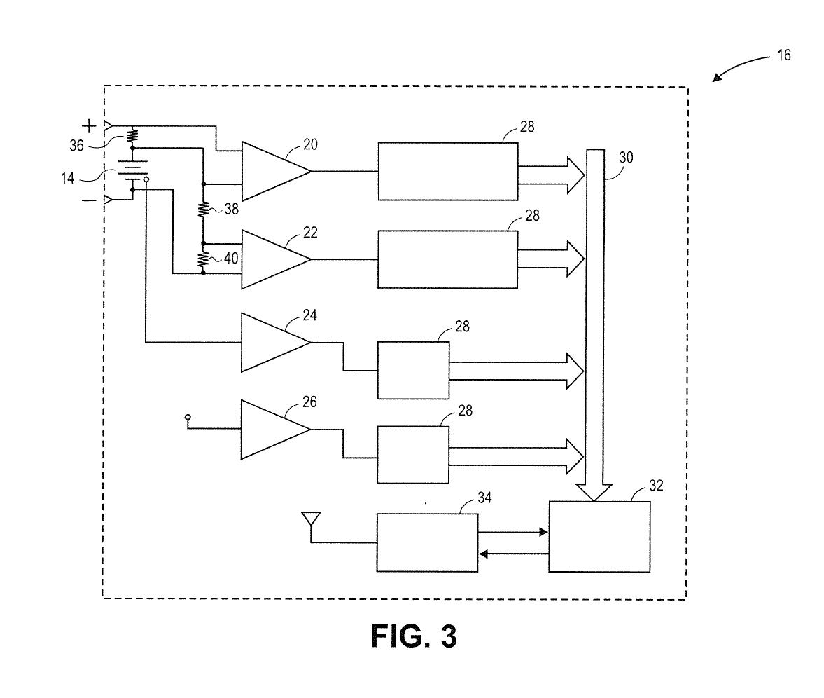

With reference to FIG. 3, the electronics module 16 of the battery metrics acquisition system 10 may include various electrical components, such as one or more sensors (e.g., a current sensor 20, a voltage sensor 22, a battery temperature sensor 24, and an ambient temperature sensor 26) for sensing metrics of the battery 14; one or more analog to digital converters 28 for converting an analog output signal of the one or more sensors to a digital signal; a data bus 30 for receiving the metrics from the one or more analog to digital converters; a processing element 32 for receiving the metrics from the data bus; memory elements (not shown) for storing the acquired metrics; and a communications interface 34 for communicating the metrics to an external computing device. The electrical components of the electronics module 16 may be individual components, such that they are located and function independently of the other components. However, in other embodiments the electrical components of the electronics module 16 may be integrated as a single unit, such as on an integrated chip, printed circuit board, printed circuit assembly, or the like. The electronics module 16 may be held within the housing 12, or one or more of the electrical components of the electronics module 16 may be located outside the housing. The components of the electronics module 16 may be powered by the battery 14 or may include a separate power source.

The one or more sensors of the electronics module 16 may include various types of sensors for sensing one or more metrics associated with the battery 14. Exemplary sensed metrics associated with the battery 14 may include the battery's bidirectional current, voltage, internal impedance, and temperature. Additionally, embodiments of the present invention may also sense metrics associated with an ambient temperature. It is also understood that acquisition times may be obtained, such that a time when each metric is acquired may be determined via the processing element 32, saved on the memory elements, and/or transmitted via the communications interface 34. The one or more sensors may include components necessary for sensing the metrics and may broadly comprise electrical contacts, resistors, and a signal amplifier (e.g., operational amplifier). For example, the current sensor 20 may acquire current information from the battery 14 and may include a first reference resistor 36 positioned in series with the battery; two electrical contacts positioned on either side of the first reference resistor for obtaining a voltage measurement across the first reference resistor; and an operational amplifier for amplifying the voltage measured across the first reference resistor. It is understood that although the operational amplifier may be sensing and/or amplifying a voltage, such voltage is related to current through Ohms Law. Thus, a current of the battery 14 can be determined by measuring a voltage across the first reference resistor 36.

The voltage sensor 22 may acquire voltage information from the battery 14 and may include a second reference resistor 38 positioned in series with a third reference resistor 40, with both the combined second and third reference resistors being positioned in parallel with the battery; two electrical contacts positioned on either side of the third reference resistor for obtaining a voltage measurement across the third reference resistor; and an operational amplifier for amplifying the voltage measured across the third reference resistor. It is understood that although the operational amplifier may be sensing and/or amplifying a voltage across the third reference resistor 40, such voltage is related to the voltage across the battery 10 through Ohms Law and Kirchoff's Voltage Law. Thus, the voltage of the battery 14 can be determined by measuring a voltage across the third reference resistor 40.

The temperatures sensors 24,26 may acquire temperature information from the battery 14 and the ambient environment, respectively, and may each include two electrical contacts in the form of a thermocouple, for obtaining a voltage measurement between the two electrical contacts; and an operational amplifier for amplifying the voltage measured across the two electrical contacts. It is understood that although the operational amplifier may be sensing and/or amplifying a voltage across the electrical contacts, such voltage is related to temperature through the specific thermocouple relationship that is dependent on types of material used in the two electrical contacts. Thus, the temperatures of the battery 14 and the ambient environment can be determined by measuring a voltage across each of the two electrical contacts of sensors 24 and 26, respectively.

The one or more analog to digital converters 28 may include any device or component that is capable of converting an analog digital signal to a digital signal. In general, the analog to digital converters 28 function to convert an amplitude and/or magnitude of an analog signal (e.g., a voltage magnitude) into a corresponding digital value that can be interpreted via the processing element 32 or other processing elements, micro-controllers, or the like. The data bus 30 may include any device or component that is electronically coupled with each sensor and functional to transmit the sensed metrics to the processing element 32.

The processing element 32 of the electronics module 16 of the battery metrics acquisition system 10 generally executes the secondary computer program of the present invention, wherein the secondary computer program is also commonly known as instructions, commands, software code, executables, applications, apps, and the like. The processing elements may include processors, microprocessors, microcontrollers, field-programmable gate arrays (FPGAs), or the like, as well as combinations thereof. The secondary computer program associated with the processing element 32 may include instructions that direct the operation of the battery metrics acquisition system 10. For instance, the secondary computer program may include instructions that direct the processing element 32 to perform the functions of receiving the one or more metrics of the battery 14 and transmitting the metrics to an external computing device via the communications interface 34, as described herein. In alternative embodiments, the processing element 32 may also perform calculations on the metrics received from the one or more sensors to independently compute status information and/or operating parameters for the battery 14. In certain embodiments, the processing elements may perform minimal processing actions on the metrics obtained from the one or more sensors. Instead, calculations and algorithms for analyzing metrics and for reporting the same may be performed by the primary computer program of the external server device and/or external computing device, which will be discussed in more detail below. Thus, the processing element 32 of the electronics module 16 may transmit the metrics to the external computing device for performing calculations. In additional embodiments, the battery metrics acquisition system 10 may write the metrics to the memory elements, discussed in more detail below, which can later be transferred to the external computing device for analysis.

As previously discussed, the processing element 32 directly associated with the battery metrics acquisition system 10 may perform minimal processing actions. Instead, processing actions (i.e., calculations and algorithms) for determining the status information and operating parameters of the battery 14 and for reporting same may be performed by an external computing device. The calculations and algorithms may be performed according to the primary computer program of the external server device and/or external computing device as opposed to stored the secondary computer program of the battery metrics acquisition system 10 so that the electronic components of the battery metrics acquisition system 10 can be used or re-used across a wide range of battery types and specifications. Thus, it should be appreciated that the primary computer program may perform all or substantially all of the steps of the method of embodiments of the present invention, and that the stored secondary computer program of the battery metrics acquisition system 10 may perform minimal processing actions. However, it should also be appreciated that the memory element of the battery metrics acquisition system 10 could store additional, if not all, code segments of both the primary and secondary computer programs, such that processing element 32 may implement any of the analyses, calculations, and/or algorithms discussed herein.

The memory elements of the electronics module 16 of battery metrics acquisition system 10 generally store the secondary computer program as well as the metrics received from the one or more sensors. The memory elements may further store other information such as data, text, graphics, videos, or other similar information, as may be necessary to carry out and perform embodiments of the present invention, as described herein. The memory elements may also be known as a “computer-readable storage medium” and may include non-transitory components such as random access memory (RAM), read only memory (ROM), flash drive memory, hard disk drives, or the like, as well as combinations thereof. The memory elements may be in electronic communication with the processing element 32, such that the processing element may access the secondary computer program and data in the memory element in a manner known in the art. In some embodiments, the memory elements may be integrated with the processing element 32, such as in a micro-controller. Certain other embodiments may provide for the memory elements to be removable from the housing 12, such as with secure digital (SD) cards, compact flash (CF) cards, writable Compact Disc, or the like. In even further embodiments, a portion, or all, of the secondary computer program may be stored externally, but may be accessible by the processing element 32 through the communications interface 34.

The communications interface 34 of the electronics module 16 allows the battery metrics acquisition system 10 to communicate with external devices, systems, computers, or networks, via a communications network discussed in more detail below. Generally, the communications interface may provide for a wireless connection, such as by radio frequency (RF) transmitters, receivers, or transceivers that utilize wireless communication protocols like GSM, CDMA, Bluetooth®, WiFi, WiMAX, or other radio or cellular protocols. In additional embodiments, the communications interface may have a wired connection, such as with electrically conductive cables, optical fibers, or the like. In embodiments that use the wired connection, the housing 12 of the battery metrics acquisition system 10 may include one or more universal connection ports, such as a Universal Serial Bus (USB), serial port, Ethernet, or FireWire connectors, to facilitate wired communications into the electronics module 16. Use of the communications interface 34 allows information and data stored on the memory element to be uploaded or otherwise transmitted to the external devices, systems, computers, or networks. Moreover, use of the communications interface 34 allows software updates to be downloaded to the memory element for implementation of code segments of the secondary computer program and stored on or associated with the memory element of the battery metrics acquisition system 10. In even further embodiments, the communications interface may provide for users to remotely control the certain functions and features of the battery metrics acquisition system 10, such as by remotely disconnecting the battery 14 from the device to which it is providing power. Such embodiments may be employed, for instance, when the battery 14 is experiencing a failure and may pose a hazard to the device or users of the device. For example, if the metrics obtained from the one or more sensors were analyzed and it was determined that the battery 14 may potentially fail, a user may remotely disconnect the battery from its associated device by opening a portion of the circuit connecting the battery with the device, such as through a switch, transistor, or the like.

Although the battery metrics acquisition system 10, described above, was detailed with respect to acquiring metrics from one or more batteries 14, it is understood that embodiments of the present invention may include apparatuses and systems for acquiring metrics from a plurality of devices. For instance, embodiments of the present invention may additionally be directed to acquiring metrics from fuses, motors, pumps, generators, heating elements, lighting elements, or other similar-type devices. The computer program, method, and system of embodiments of the present invention may be used to monitor such device's metrics and wirelessly transmit such metrics to a computing device for further analysis. For example, a fuse metric acquisition system, which may be similar to the battery metrics acquisition system 10, may monitor an electrical fuse by acquiring metrics associated with the fuse. The metrics may include, for instance, an electrical current of the fuse, a temperature of the fuse, or the like. The metrics may be acquired and saved on memory elements of the fuse metric acquisition system, and/or the metrics may be transmitted to an external server/computing device for further analysis. It should be understood that the fuse metrics acquisition system is provided for purely exemplary purposes, and embodiments of the present invention may include systems for acquiring, storing, and transmitting metrics associated with a plurality of devices.

### MONITORING AND ANALYSIS SYSTEM

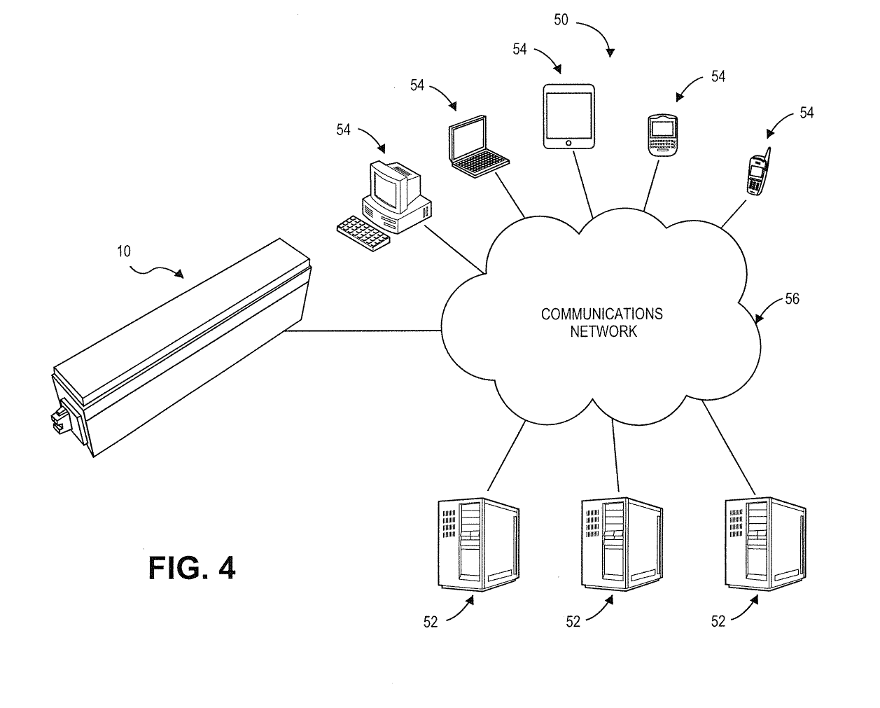

As described above, embodiments of the present invention provide for battery metrics to be provided to and analyzed by external sever devices and/or external computing devices. Such embodiments of the present invention may be implemented in hardware, software, firmware, or combinations thereof using monitoring and analysis system 50, shown in FIG. 4, which broadly comprises server devices 52, external computing devices 54, a communications network 56, and one or more battery metrics acquisition systems 10, as were previously described. The server devices 52 may include computing devices that provide access to one or more general computing resources, such as Internet services, electronic mail services, data transfer services, and the like. The server devices 52 may also provide access to a database that stores information and data necessary for the implementation of the primary computer program, the method, and other embodiments of the present invention. The primary computer program, server devices, and computing devices illustrated and described herein are merely examples of programs and computing devices that may be used to implement aspects of embodiments of the invention and may be replaced with other programs and computing devices without departing from the scope of the invention.

The server devices 52 and external computing devices 54 may include any device, component, or equipment with a processing element and associated memory elements. The processing element may implement operating systems, and may be capable of executing the primary computer program, which is also generally known as instructions, commands, software code, executables, applications (“apps”), and the like. The processing element may include processors, microprocessors, microcontrollers, field programmable gate arrays, and the like, or combinations thereof. The memory elements may be capable of storing or retaining the secondary computer program and may also store data, typically binary data, including text, databases, graphics, audio, video, combinations thereof, and the like. The memory elements may also be known as a “computer-readable storage medium” and may include random access memory (RAM), read only memory (ROM), flash drive memory, floppy disks, hard disk drives, optical storage media such as compact discs (CDs or CDROMs), digital video disc (DVD), Blu-Ray™, and the like, or combinations thereof. In addition to these memory elements, the server devices 52 may further include file stores comprising a plurality of hard disk drives, network attached storage, or a separate storage network. The functionality of server devices 52 may also be distributed amongst many different computers in a cloud computing environment.

At least one of the server devices 52 may operate and/or host a website accessible by at least some of the external computing devices 54. The server device 52 may include conventional web hosting operating software, an Internet connection, such as a cable connection, satellite connection, DSL converter, or ISDN converter, and is assigned a URL and corresponding domain name so that the website hosted thereon can be accessed via the Internet in a conventional manner. In embodiments of the invention where the server device 52 implements a mobile application (i.e., an “app”), the server device may host and support software and services of proprietary mobile application providers, such as Google, Apple, and Blackberry. For example, some server devices 52 may support Google Android mobile applications, while other server devices may support Apple iPhone mobile applications.

The external computing devices 54 may specifically include mobile communication devices (including wireless devices), work stations, desktop computers, laptop computers, palmtop computers, tablet computers, portable digital assistants (PDA), smart phones, and the like, or combinations thereof. Various embodiments of the external computing device 54 may also include voice communication devices, such as cellular and/or mobile phones. In preferred embodiments, the external computing device 54 will have an electronic display, such as a cathode ray tube, liquid crystal display, plasma, or touch screen that is operable to display visual graphics, images, text, etc. In certain embodiments, the primary computer program of the present invention facilitates interaction and communication through a graphical user interface (GUI) that is displayed via the electronic display. The GUI enables the user to interact with the electronic display by touching or pointing at display areas to provide information to the user control interface, which is discussed in more detail below. In additional preferred embodiments, the external computing device 54 may include an optical device such as a digital camera, video camera, optical scanner, or the like, such that the computing device can capture, store, and transmit digital images and/or videos. The external computing devices 54 may include a user control interface that enables one or more users to share information and commands with the computing devices or server devices 52. The user interface may facilitate interaction through the GUI described above or may additionally comprise one or more functionable inputs such as buttons, keyboard, switches, scrolls wheels, voice recognition elements such as a microphone, pointing devices such as mice, touchpads, tracking balls, styluses.

The communications network 56 of the system 50 may be the same network described with respect to the communications interface 32 of the battery metrics acquisition system 10. The communications network 56 may also be a combination of several networks. For example, the external computing devices 54 may wirelessly communicate with another external computing device 54 or a server 52 in a place of business or other building via a Wi-Fi network, which in turn is in communication with one or more external servers 52 or battery metrics acquisition systems 10 via the Internet, cellular network, or other communications network.

Both the server devices 52 and the computing devices 54 may be connected to the communications network 56. Server devices 52 may communicate with other server devices 52, external computing devices 54, and/or the one or more battery metrics acquisition systems 10 through the communications network 56. Likewise, external computing devices 54 may communicate with other external computing devices 54, server devices 52, and/or one or more battery metrics acquisition system 10 through the communications network 56. Thus, the server devices 52 and the external computing devices 54 may include the appropriate components to establish a connection with the communications network 56.

The primary computer program of the present invention may run on external computing devices 54 or one or more server devices 52. Alternatively, as previously described, the primary computer program may run on one or more battery metrics acquisition systems 10. Additionally, a first portion of the program, code, or instructions may execute on a first server device 52 or a first external computing device 54, while a second portion of the program, code, or instructions may execute on a second server device 52 or a second external computing device 54. In some embodiments, other portions of the program, code, or instructions may execute on other server devices 52 or external computing devices 54 as well. For example, information and data may be stored on a memory element associated with the server device 52, such that the information and data is remotely accessible to users of the primary computer program via one or more external computing devices 54. Alternatively, the information and data may be directly stored on the memory element associated with the one or more external computing devices 54. In additional embodiments of the present invention, a portion of the information and data may be stored on the server device 52, while another portion may be stored on the one or more external computing devices 54. The various calculations and analyses described herein as being performed by or using the primary computer program may actually be performed by one or more computers, processors, or other computational devices, such as the external computing devices 54 or server devices 52 independently or cooperatively executing portions of the primary computer program.

In certain embodiments of the present invention, the primary computer program may be embodied in a stand-alone program downloaded on a user's computing device 54 or in a web-accessible program that is accessible by the user's computing device 54 via the communications network 56. For the stand-alone program, a downloadable version of the primary computer program may be stored, at least in part, on the server device 52. A user may download at least a portion of the primary computer program onto the computing device 54 via the network 56. In such embodiments of the present invention, the primary computer program may be implemented as an “application,” such as an “app” for a mobile device. After the primary computer program has been downloaded, the program can be installed on the computing device 54 in an executable format. The executable form of the program permits the user to access embodiments of the present invention via an electronic resource, such as a mobile “app” or website. For the web-accessible computer program, the user may simply access the computer program via the network 56 (e.g., the Internet) with the external computing device 54.

Once a user has access to the electronic resource, via the primary computer program installed on a user's external computing device 54 or the web, certain embodiments may provide for users to create user accounts with which to access the electronic resource. The user accounts may be stored within the memory elements of the external computing device 54, the server 52, or in the associated database. Certain embodiments of the present invention may provide for one or more types of accounts, such as a general user account and admin account. Each type of user account may provide their respective users with unique roles, capabilities, and permissions with respect to implementing embodiments of the present invention. Each account may be associated with a username and/or password required for accessing the account by a particular user. In addition, embodiments of the present invention may include any number and/or any specific types of account as may be necessary to carry out the functions, features, and/or implementations of the present invention.

A general user account is an account created by or for general users, such as staff, administrators, managers, or the like, who may be required to implement embodiments of the present invention to receive and analyze metrics obtained from one or more battery metrics acquisition systems 10. The admin account is an account created by or for administrative users, who may be responsible for administrating and maintaining embodiments of the present invention. For instance, the admin account may be used to create and maintain general user accounts and/or to generally oversee embodiments of the present invention. Each user that obtains an account may be provided with or select a particular username and password for accessing the account and other embodiments of the present invention as will be discussed in more detail below. Further, when establishing an account, users may be required to enter various pieces of identification information, such as a name, address, email address, telephone number, or the like. In particular, the email address and telephone number may be implemented by embodiments of the present invention to send alerts and notifications, as will be discussed in more detail below.

### OPERATION

The battery metrics acquisition system 10 of embodiments of the present invention is directed to acquiring metrics of the one or more batteries 14 and transmitting the battery metrics for analysis and/or display by a server 52 and/or an external computing device 54. In particular, the communications interface 34 of the battery metrics acquisition system 10 transmits the sensed battery metrics to the server device 52, and specifically, to the memory elements and/or database associated with the server device. The server device 52 may store the received battery metrics in one or more databases. The metrics may be stored for organizational, referencing, and/or analyses purposes, as will be discussed in more detail below. The transmission of the sensed battery metrics from the battery metrics acquisition system 10 and to the server device 52 may preferably be performed wirelessly via the communications network 56. The transmission of sensed battery metrics may be performed instantaneously in real-time, or the transmission may be performed at desired intervals, such as every hour, every thirty minutes, every minute, etc. The desired intervals may be selected by users of embodiments of the present invention. In further embodiments of the present invention, metrics may be transmitted instantaneously, or nearly instantaneously, in real-time. Once the metrics have been received by the server device 52, the metrics may be available for further analysis via the primary computer program and for display via the external computing devices 54.

The external computing devices 54 may be used by users who are required or who desire to review the metrics and to determine status information and/or operating parameters of one or more battery metrics acquisition systems 10 based on the received metrics. As previously described, the acquired metrics may broadly include the battery's current, voltage, and temperature, as well as ambient temperature. In embodiments of the present invention, algorithms executed by the primary computer program use the received battery metrics, along with other known battery specifications, to determine desired status information and/or operating parameters. Exemplary battery status information may include, for instance: a state of charge, a state of health, or other similar battery status characteristic information. A state of charge is generally defined as an amount of electrical energy remaining in a battery. Contrastingly, a state of health is generally defined as an overall condition of a battery and/or a battery's capability to operate as compared with a new battery. It should be understood that certain types of status information may be directly measured by analyzing certain metrics and/or operating parameters of the battery, which are discussed in more detail below. For example, the state of charge for a battery may be determined by: integrating the battery current over time; comparing the battery voltage with the battery capacity for a given temperature; or measuring battery impedance.

Exemplary battery operating parameters may include changes in battery metrics over time. For instance, the operating parameters may include changes in battery voltage, battery current, battery capacity, battery impedance, battery temperature, and ambient temperature over time (i.e., time rates of change). Operating parameters may additionally include various individual metrics being compared with other metrics, such as: battery temperature versus battery current, battery temperature versus battery capacity, or any other combination of compared metrics that may be required for analysis by a user.

An illustrative example of a battery operating parameter that may be used to determine a condition of a battery is the time rate of change of the battery's internal impedance. In general, a battery may conceptually be represented as a voltage source in series with an impedance. This impedance may also be referred to as an internal impedance or an internal resistance. Because of the existence of the internal impedance, a battery voltage measured when no load is applied to the battery will generally be greater than the battery voltage measured when a load is applied. Such a voltage disparity is the result of the current flowing through the internal impedance when a load is applied to the battery, thus causing a voltage drop. Over time, the internal impedance of most batteries will increase, such that after a sufficient amount of time, the internal impedance is too high for the battery to operate sufficiently. Embodiments of the present invention provide for a determination of the time rate of change of a battery's internal impedance, and further provide for a projection or estimation of when the internal impedance will reach a level requiring the user to replace the battery.

In more detail and with reference to FIG. 3, the battery metrics acquisition system 10 may obtain the appropriate metrics required to determine the time rate of change of the battery 14's internal impedance. To begin, an unloaded (or minimally loaded) battery voltage of the battery 14 is determine by measuring, via voltage sensor 22, the voltage across resistor 40 while no load is applied to the battery. From Ohm's Law and Kirchhoff's Voltage Law, the unloaded battery voltage can thus be determined by adding the voltage measured across resistor 40 with the voltage calculated to be present across resistor 38. Next, a battery voltage is determined while a load is applied to the battery 14. Once again, the voltage across resistor 40 is measured to determine the loaded battery voltage of battery 14. In addition, a voltage across resistor 36 is determined by current sensor 20. As was previously described, the current delivered by battery 14 may also be determined, via Ohm's Law, from the voltage measure across resistor 36 divided by a resistance value of the resistor 36. Therefrom a voltage across the battery 14'internal impedance (i.e., an impedance voltage) may be determined by subtracting the battery's loaded voltage and the voltage across resistor 36 from the unloaded battery voltage. Finally, the internal impedance may be determined by dividing the battery 14's impedance voltage by the current delivered by the battery while the load is being applied. Of note, such a determination of the internal impedance may be made without requiring the battery 14 to be removed from the battery metrics acquisition system 10.

The internal impedance metrics for the battery 14 may be determined over time, such that embodiments of the present invention provide for a determination of a time rate of change of the battery's internal impedance. As will be described in more detail below, such an operating parameter may be used to notify and alert users of embodiments of the present invention when the battery 14 is nearing the end of its useful life and should thus be replaced.

Further, embodiments of the present invention provide for certain known battery specifications to be entered and stored in the server device 52 and/or the associated database for use in analyzing the battery metrics and for determining battery status information and/or operating parameters of specific types of batteries 14. Known battery specifications may broadly include: battery chemistry, battery structure (e.g., number of cells, cell construction, etc.), initial battery capacity, initial battery impedance, battery discharge curves (i.e., voltage versus capacity), temperature characteristics (i.e., voltage versus discharge time at a given temperature), self-discharge characteristics (capacity versus non-use time), battery cycle life (i.e., capacity versus number of charge/discharge cycles), or other similar known specification information. The known battery specifications may be obtained from a manufacturer of the battery 14. Thus, the known battery specifications may be used along with the acquired battery metrics to obtain the state of charge, the state of health, or other battery status information and/or operating parameters. In even further embodiments, the acquired battery metrics, the status information, and the operating parameters obtained from each of the one or more batteries 14 included in the battery metrics acquisition system 10 may be stored in the server device 52 for further analysis. After analysis, the acquired battery metrics, the status information, and the operating parameters may become part of the known battery specifications, such that they can be used for future comparisons and analyses with other batteries, or may additionally be used for alerting and notifying users as to battery statuses and performances, as will be discussed in more detail below.

Embodiments of the present invention provide for each of the one or more battery metrics acquisition systems 10 included in the monitoring and analysis system 50 to have an individually associated electronic resource (i.e., web page or mobile app) that can be displayed via a user interface of the user's external computing device 54. The electronic resource may provide users with real-time metrics as transmitted by each battery metrics acquisition system 10 and may further provide users with the status information and the operating parameters as determined from the metrics and the known battery specifications. Such metrics, status information, and operating parameters may be presented in various forms, such as by numerical values, graphs, charts, tables, or the like. The electronic resource may provide multiple individual metrics, status information, and operating parameters on a single screen of the electronic resource, via multiple panes. In addition, embodiments of the present invention may provide for the creation of a customizable electronic resource where users can personalize specific metrics, status information, and/or operating parameters to be presented. The electronic resource may additionally, or alternatively, be configured to include a summary screen that provides summary information, such as a summary of all metrics, status information, and operating parameters, for any or all of the battery metrics acquisition systems 10 included in the system 50. Alternatively, the electronic resource may be used to view metrics obtained from a single battery metrics acquisition system 10.

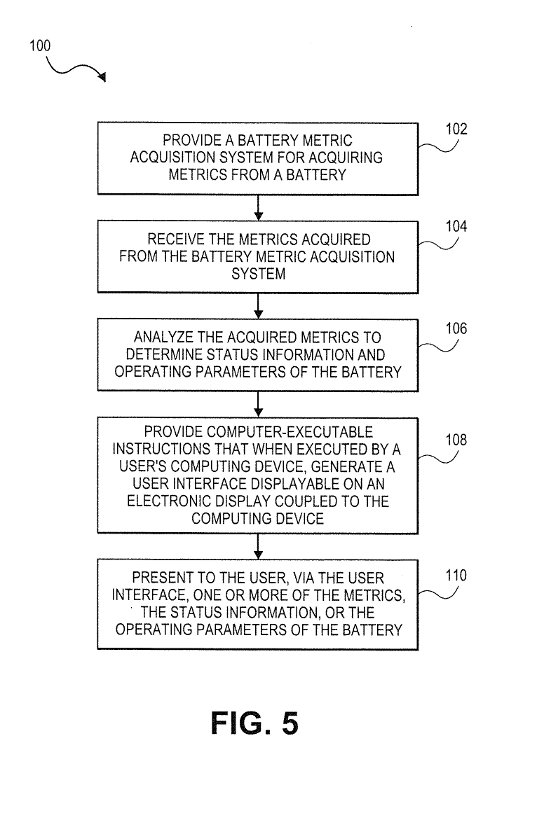

Embodiments of the present invention include a method 100 for acquiring metrics from a battery, as illustrated in FIG. 5. The method 100 includes the initial Step 102 of providing a battery metrics acquisition system for acquiring metrics from a battery. Step 104 includes receiving the metrics acquired from the battery metrics acquisition system. In Step 106, embodiments of the present invention provide for analyzing the acquired metrics to determine status information and operating parameters from of the battery. In Step 108, a user is provided with a set of computer-executable instructions that when executed by an electronic device, generate a user interface displayable on an electronic display coupled to the user's electronic device. Finally, in Step 110, one or more metrics, the status information, or the operating parameters of the battery may be presented to the user, via the user interface of the user's computing device.

Embodiments of the present invention provide for users to enter and set threshold values for certain metrics, status information, and operating parameters for batteries 14 from which metrics are being acquired by a battery metrics acquisition system 10. The electronic resource may thus provide users with alerts or notifications that inform the users as to the status of a particular battery being monitored by a battery metrics acquisition system 10. The users may implement alert or notification features that actively inform the users, in real-time, as to whether certain metrics, status information, and/or operating parameters have violated the threshold values. For instance, if a battery's voltage or capacity level drops rapidly, the system 50 may provide for the user's external computing device 54 to receive an alert, such as a page, text, email, or the like, which indicates that the user should prepare for performing maintenance, recharging, repairing, or replacing the battery. As an additional example, user may receive an alert if embodiments of the present invention determine that the battery 14's internal impedance is beginning to rise, thus indicating an imminent failure. In certain embodiments, such an alert may also indicate a projected failure date and/or time, such that the user can determine when best to replace the battery. Such alerts may be sent to the email address and/or telephone number associated with the user's account. In additional embodiments, the alert or notification may be provided in the form of general audio and/or visual alerts displayed on the electronic display of the user's external computing device 54.

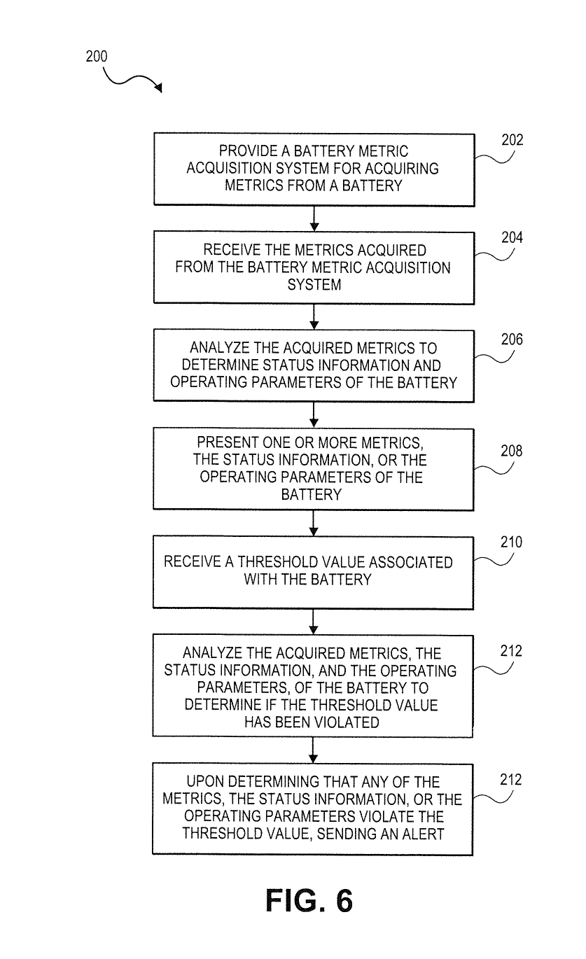

Thus, embodiments of the present invention additionally include a method 200 for acquiring metrics from a battery, as illustrated in FIG. 6. The method 200 includes the initial Step 202 of providing a battery metrics acquisition system for acquiring metrics from a battery. Step 204 includes receiving the metrics acquired from the battery metrics acquisition system. In Step 206, embodiments of the present invention provide for analyzing the acquired metrics to determine status information and operating parameters of the battery. In Step 208, one or more metrics, the status information, or the operating parameters of the battery are presented. In Step 210, a threshold value associated with the battery is received. In Step 212, the acquired metrics, the status information, and the operating parameters of the battery are analyzed to determine whether any of such metrics, the status information, or the operating parameters violates the threshold value. Finally, in Step 214, upon determining that any of the metrics, the status information, or the operating parameters violate the threshold value, sending an alert.

In additional embodiments, the user may create status reports that report historical data of the metrics, status information, and/or operating parameters of any or all of the batteries 14 included in the one or more battery metrics acquisition systems 10. These status reports may be stored on the server device 52 or the external computing device 54 so as to create a history or log of battery metrics, status information, and/or operating parameters. Thus, embodiments of the present invention provide for obtaining historical data that the user can review or document. The status reports may be set to be created automatically without user input, thus allowing users to forgo the continual manual monitoring of the metrics, status information, and/or operating parameters associated with any or all of the batteries 14 of the one or more battery metric acquisition systems 10. Embodiments of the present invention may further provide for the battery metrics, status information, operating parameters, known battery specification, and historical data to be used to test battery performances and/or to perform quality analysis on new or used batteries. Such performance tests or quality analyses may be performed, for instance, at a battery manufacturing research facility.

Embodiments of the present invention may also notify the users when it is time to replace a battery 14 or other various components of the battery metrics acquisition system 10. For instance, users may be alerted when a battery has reached the end of its useful life and it is time to replace the battery. Such a determination may be made based on the acquired battery metrics, the status information, the operating parameters, and the known battery specifications, which were previously described. In certain embodiments, such a determination may specifically consider the time rate of change of the battery 14's internal impedance, the battery voltage, the battery and ambient temperatures, the battery's charge cycles, and the battery capacity. However, it is understood that embodiments of the present invention provide for any of the acquired battery metrics, the status information, the operating parameters, or the known battery specifications to be used to measure the condition of the battery 14.

Because the components of the battery metrics acquisition systems 10 may be interchangeable with other batteries (of similar or differing types), the battery metrics acquisition system 10 can be immediately integrated with and used on another battery of similar or differing types. Thus, it is understood that the components of the electronics module 16 are recyclable for use with a plurality of batteries. In even further embodiments, the batteries 14 included in the battery metrics acquisition system 10 may have recyclable cells, such that user can recycle the cells when the batteries 14 reach the end of their useful life.

Additional embodiments of the present invention may be implemented to predict future battery life. Such predictions may for instance be based on the battery metrics, status information, operating parameters, known battery specification, or based on historical data for the particular battery. For example, a hospital may use a particular defibrillator and its accompanying battery more often than another defibrillator located elsewhere in the hospital. The primary computer program of the present invention may use this information to predict the battery life for the particular defibrillator that is used more often. In the example, embodiments of the present invention may determine that the battery on the defibrillator that is used more often will need to be replaced twice as soon as a battery used on the defibrillator used less often. As another non-limiting example, because the ambient and operating temperature of the battery may affect battery life, the measurement of these metrics may allow embodiments of the present invention to predict a battery life according to the temperatures sensed by the battery metrics acquisition system 10. Additionally and as described above, because the known battery specifications are stored in the server device 52 or its associated database, embodiments of the present invention may incorporate the use of such known battery specifications to assist in calculating battery life and predicting future battery life. For instance, a user could use historical data from previously-used batteries to develop trends on future statuses and/or parameters of batteries presently or projected to be in use that are of the same type as the previously-used batteries.

In even further embodiments of the present invention, the users may prepare a variety of reports regarding the battery metrics acquisition system 10 by providing charts, graphs, or other desired information for future use, review, and documentation by the user or the user's employer. In addition, the user may prepare custom reports for each of the one or more battery metrics acquisition systems 10. Such information may be helpful for legal and recordkeeping requirements, as well as for reducing insurance costs as evidence of properly operating a device if the device is accused of being faulty. The information may also be used to quickly and easily determine which battery metrics acquisition system 10 has a battery 14 in need of maintenance or replacement, especially for entities having numerous battery powered devices that require continual maintenance and observation.

Embodiments of the present invention may also provide users with information for regarding new battery-related products, battery maintenance techniques, including techniques for extending battery life, battery replacement, or the like. Such information can be targeted to the user based on known user needs determined from battery metrics, status information, operating parameters, known battery specification, or based on historical data for the particular battery. Examples of known user needs may include known types of batteries used by the user, types of devices powered by the batteries, and the geographical area of the user (e.g., colder vs. warmer climates). For instance, although certain battery-powered devices may normally call for the use of high-cost batteries, the present invention may determine from the historical data of the user's previous batteries that the user's devices may be operated by lower cost, alternative batteries. As a specific, non-limiting example, a fleet vehicle manager with an operation located in a cold climate generally purchases costly vehicle batteries that are rated for extremely cold temperatures. Embodiments of the present invention may be used to determine that based on the battery metrics, status information, operating parameters, known battery specification, and historical data obtained from battery metrics acquisition systems integrated on the manager's vehicles, it may be beneficial to purchase lower cost batteries that are not rated as highly for cold temperature but that would operate satisfactorily for the temperatures and operational requirements of the manager's vehicles.

In certain other embodiments, the external computing devices 54 may be used by users to remotely control the functionality of the one or more battery metrics acquisition system 10 or their associated batteries 14. For example, a user who is monitoring, via an external computing device 54, the metrics of a battery metrics acquisition system 10 may observe that the battery's operating parameters are indicating an imminent failure. If the failure may be dangerous or pose a hazard to its associated device, the user may be able to remotely disconnect the battery from the circuitry of the device (e.g., by activating an electronic switch or otherwise creating an open circuit). Thus, embodiments of the present invention provide for users to not only passively view and analyze metrics, but to also actively manage certain functions and features of the battery metrics acquisition system 10.

Although the invention has been described with reference to the preferred embodiment(s), it is noted that equivalents may be employed and substitutions made herein without departing from the scope of the invention. For instance, as was previously described, embodiments of the present invention may be applied to devices other than batteries, such as fuses, motors, pumps, generators, and heating or lighting elements. Thus, for instance, embodiments of the present invention may be used to obtain metrics from such devices; determine status information and operating parameters based on the metrics and/or known specifications; and presenting the metrics, status information, and/or operating parameters to a user. Embodiments of the present invention may also be implemented to notify a user when certain metrics, status information, or operating parameters violated predefined threshold levels.

As a non-limiting example as previously described, embodiments of the present invention may be used to acquire metrics from an electrical fuse. Embodiments of the present invention may use the acquired metrics and/or any known specifications to determine status information and operating parameters of the fuse. Thus, a user may be presented with determined operating parameters to observe, in real-time, how the electrical fuse is functioning. In addition, the user may set a current threshold value for the fuse, such that if the measured current drops below the threshold value, the user is provided with an alert or notification, which indicates that the user needs to perform maintenance on or otherwise replace the electrical fuse.

Although this invention has been described with its preferred embodiment(s), it is noted that equivalents may be employed and substitutions made herein without departing from the scope of the invention.

Having thus described various embodiments of the invention, what is claimed as new and desired to be protected by Letters Patent includes the following:

1. A system for acquiring metrics from a battery, comprising:
a battery metric acquisition system for acquiring metrics from a battery; and
a non-transitory computer readable storage medium with a computer program stored thereon, wherein the computer program instructs a processor to perform the following steps—
receive the metrics acquired by the battery metrics acquisition system;
analyze the metrics to determine status information and operating parameters of the battery;
provide to a user a set of computer-executable instructions that when executed by a user's computing device, generate a user interface displayable on an electronic display coupled to the user's computing device; and
present to the user, via the user interface, one or more of the metrics, the status information, or the operating parameters of the battery.

2. The system of claim 1, wherein the metrics are comprised of one or more of the following: a voltage of the battery, a current of the battery, a temperature of the battery, and an ambient temperature.

3. The system of claim 1, wherein the status information is comprised of one or more of the following: a status of charge of the battery or a status of health of the battery.

4. The system of claim 1, wherein the operating parameters include time rates of change of the metrics or one or more of the metrics compared with another metric.

5. The system of claim 1, wherein the computer program further instructs the processor to:
receive a threshold value associated with the battery from the user;
analyze the metrics, the status information, and the operating parameters to determine whether any of the metrics, the status information, or the operating parameters violate the threshold value;
upon determining that any of the metrics, the status information, or the operating parameters violate the threshold value, send an alert the computing device of the user.

6. The system of claim 5, wherein the alert includes a text message, an email, or a page.

7. The system of claim 1, wherein the step of analyzing the metrics to determine status information and operating parameters includes analyzing known battery specifications.

8. The system of claim 7, wherein the known battery specifications include one or more of the following: a battery chemistry, a battery structure, a battery discharge curve, a battery temperature characteristic, a self-discharge characteristic, and battery cycle life.

9. The system of claim 1, wherein the step of presenting to the user the one or more of the metrics, the status information, or the operating parameters of the battery includes presenting the metrics, the status information, or the operating parameters in real-time.

10. The system of claim 1, wherein the step of presenting to the user the one or more of the metrics, the status information, or the operating parameters of the battery includes presenting the metrics, the status information, or the operating parameters in a periodic timeframe, with the period of the timeframe selected by the user.

11. A method for acquiring battery metrics from a battery, comprising the steps of:
providing a battery metric acquisition system for acquiring metrics from a battery;
receiving the metrics acquired by the battery metrics acquisition system;
analyzing, via a processor, the metrics to determine status information and operating parameters; and
presenting one or more of the metrics, the status information, or the operating parameters of the battery;
receiving a threshold value associated with the battery;
analyzing, via a processor, the metrics, the status information, and the operating parameters to determine whether any of the metrics, the status information, or the operating parameters violate the threshold value;
upon determining that any of the metrics, the status information, or the operating parameters violate the threshold value, sending an alert.

12. The method of claim 11, wherein the metrics are comprised of one or more of the following: a voltage of the battery, a current of the battery, a temperature of the battery, and an ambient temperature.

13. The method of claim 11, wherein the status information is comprised of one or more of the following: a status of charge of the battery or a status of health of the battery.

14. The method of claim 11, wherein the operating parameters include time rates of change of the metrics or one or more of the metrics compared with another metric.

15. The method of claim 11, wherein the step of sending an alert includes sending a text message, an email, or a page.

16. The method of claim 11, wherein the step of analyzing the metrics to determine status information and operating parameters includes analyzing known battery specifications.

17. The method of claim 16, wherein the known battery specifications include on or more of the following: a battery chemistry, a battery structure, a battery discharge curve, a battery temperature characteristic, a self-discharge characteristic, and battery cycle life.

18. The method of claim 11, wherein the step of presenting the one or more of the metrics, the status information, or the operating parameters of the battery includes presenting the metrics, the status information, or the operating parameters in real-time.

19. The method of claim 11, wherein the step of presenting one or more of the metrics, the status information, or the operating parameters of the battery includes presenting the metrics, the status information, or the operating parameters in a periodically.
